(19) United States
(12) Patent Application Publication
(10) Pub. No.: US 2003/0087198 A1
(43) Pub. Date: May 8, 2003

(54) Three-dimensional polymer nano/micro molding by sacrificial layer technique

(76) Inventors: Saman Mangala Dharmatilleke, Westerville, OH (US); H. Thurman Henderson, Cincinnati, OH (US)

Correspondence Address: Dr. H. Thurman Henderson, 4010 Clifton Ave., Cincinnati, OH, 45220-1108, US

(21) Appl. No.: 10/246,610

(22) Filed: Sep. 18, 2002

Related U.S. Application Data
(60) Provisional application No. 60/323,271, filed on Sep. 19, 2001.

(51) Int. Cl. G03F 7/00

(52) U.S. Cl. 430/320; 430/322

(57) ABSTRACT

A procedure is presented herein for formation of NEMS/MEMS components and systems with direct arbitrary three-dimensionality for the first time in NEMS/MEMS fabrication. This method leads also to a simple and effective external “quick-connection” interconnect scheme where ordinary fused silica tubes may be press-fitted into the surface opening of this system to withstand high pressure. This method may be extended for connection of multiple levels of polymer fluidic motherboards together using small sections of fused silica tubing, with no loss of stacking volume because of the lack of any connector lips or bosses. This scheme gives the flexibility of allowing multiple stacks of polymeric 3-D components (motherboards) while being able to control the channel lengths within the stacks as desired. Mixing chambers can also be molded in a single silicone elastomer (or other material) layer, because true three-dimensionality is trivially possible without the complexity of multi stacked lithography.

### CROSS REFERENCE TO RELATED APPLICATIONS

This is the complete documentation for non provisional patent application bearing number 60/323,271 filed on Sep. 19, 2001.

### STATEMENT REGARDING FED SPONSORED R&D

This invention was made with government support under contract F30602-97-2-0102 awarded by the Air Force. The government has certain rights in this invention.

### TECHNICAL FIELD OF THE INVENTION

The present invention relates to the fabrication of nanofluidic and/or microfluidic systems and devices.

### BACKGROUND OF THE INVENTION

Intensive efforts have been recently underway, particularly in the biomedical, NEMS (nano electro mechanical systems) and MEMS (micro electro mechanical systems) fields to develop nanofluidic and/or microfluidic devices and systems in polymers towards realization of the much pursued biochemical “lab-on-a-chip”. One of the major problems is that of achieving small (order of a few hundred micrometers or less in diameter) fluidic channels in three-dimensions to carry various fluids and reagents from point to point within and out of the polymer or other “motherboard”.

Others have experimented with planar optical lithographic and other polymer molding techniques, followed by bonding of multiple layers of planar polymer to form three-dimensional (3-D) structures. For example, at the NEMS or MEMS level a 3-D structure is necessary to achieve mixing because of the small Reynolds numbers involved. The methods used by others are clumsy, expensive and time consuming, and configurations are inherently limited.

In the provisional application No. (60/323,271) the inventors have disclosed further methods, structures and devices related to the present invention as described in the following papers authored by the present inventors.

(1) Three-dimensional silicone device fabrication and inter-connection scheme for microfluidic applications using sacrificial wax layers. Saman Dharmatilleke and H Thurman Henderson.

(2) Three-dimensional silicone microfluidic interconnection scheme using sacrificial wax filaments. Saman Dharmatilleke, H. Thurman Henderson et al.

### BRIEF SUMMARY OF THE INVENTION

A procedure is presented herein for formation of true three-dimensionality of “nanoplumbing” and or “microplumbing” (including microvalving) in polymer (such as silicone elastomer, PDMS, poly amide, epoxy, plastic, etc.), by molding the polymer to encapsulate a pre-formed network of sacrificial wax threads or other connected wax configurations (or any sacrificial layer such as photo resist, metal, silicon, etc.) which are ultimately to become nano/micro channels, devices and cavities in the molded polymer. When these sacrificial areas are etched away with a solvent (such as acetone or an etchant or heat treatment) precise cavities, channels, and capillaries result with direct arbitrary three-dimensionality for the first time in nano/microfabrication.

### ADVANTAGES AND POTENTIALS OF MOLDED POLYMERIC MICRO DEVICES

By using the polymeric scheme described here, the sensors or the nanofluidic and/or microfluidic devices can be fabricated with embedded channels, reservoirs, valves, etc. inside the substrate. This eliminates the need of each component being individually connected to realize a system. Also, if required, the polymeric motherboards allow for much easier interconnections by use of this scheme. A transparent polymer (silicone elastomer or PDMS or any other transparent material) offers higher visibility through the casting, rendering trouble shooting much easier. Molded polymer such as silicone nano/micro systems can, of course, withstand higher shock than can the more conventional rigid silicon or glass systems. These polymer systems can also be implanted in humans, since many of the polymers are bio-compatible.

### BRIEF DESCRIPTION OF THE DRAWINGS

FIG. 1. Schematic of a normallyclosed pinch valve in an openposition. One of the magnetic pole pieces is reversed for a normally-open valve. This valve employs a nano/micro electromagnetic actuator and a magnetic spring.

FIG. 2. schematic of a normally-closed pinch valve in an openposition. The valve in the molded motherboard substrate employs a nano/micro magnetostrictive actuator.

FIG. 3. An illustrative example of a method for pulling wax thread from wax melt, for use as a sacrificial layer in forming microchannels in molded substrate

FIG. 4. Schematic of interconnection of two molded nano/microfluidic polymer devices or systems in a stand-off scheme.

FIG. 5. Schematic of interconnection of two molded nano/microfluidic devices or systems in a closed scheme.

### DETAILED DESCRIPTION OF THE DRAWINGS

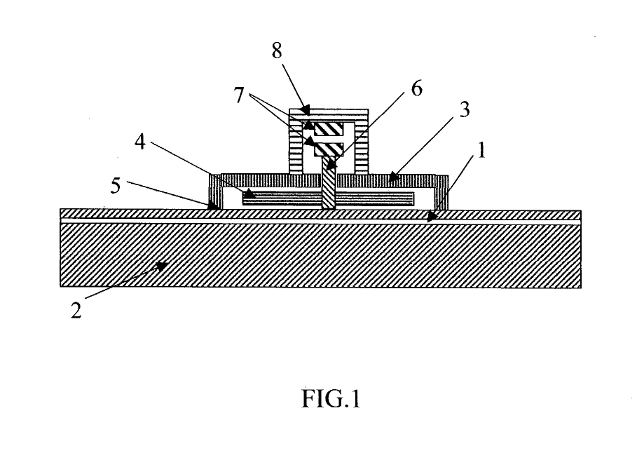

FIG. 1 is the schematic of a normally closed pinch valve in open position. A microchannel (1) is formed in silicone elastomer substrate (2) by etching away of sacrificial wax (or similar sacrificial material). An electric solenoid (3) which actuates the valve by means of attracting the ferromagnetic disk (4) towards the solenoid (3) is bound to the silicone substrate by setting in original mold (5). A pinching shaft (6) is attached to the ferromagnetic disk (5) through a hole in the center of the ferromagnetic disk (5), which pinches the microchannel formed in silicone. Two permanent magnets (7) are used to act as a magnetic spring. One of the permanent magnets (7) is attached to the end of the pinching shaft (6) and the other permanent magnet (7) is attached to the magnet mount (8). The magnets (7) are mounted such that like poles face each other.

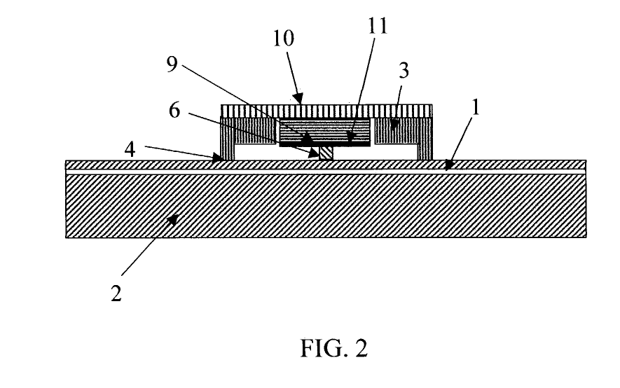

FIG. 2 is the schematic of a normally closed pinch valve in open position. A microchannel (1) is formed in silicone elastomer substrate (2) by etching away of sacrificial wax (or similar sacrificial material). An electric solenoid (3) which actuates the valve by means of contracting the disk (9) made of magnetostrictive material is bound to the silicone substrate by setting in original mold (5). One face of the disk made of magnetostrictive material (9) is attached to the disk holder (10). A metal disk (11) is attached to the other face of the magnetostrictive disk (9). The disk holder (10) is attached to the solenoid (3). The pinching shaft (6) is attached to the metal disk (11) at the center and is at right angles to it. Pinching shaft (6) pinches the microchannel (1) formed in silicone elastomer (2) to close the valve.

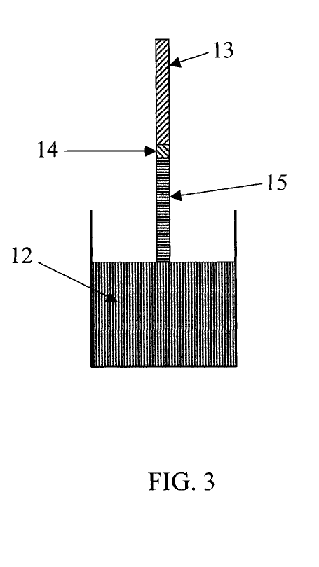

FIG. 3 illustrates the method used for making wax thread and filaments. Wax is heated until it melts, in a container (16). A cold wax seed (14) is attached to one end of the wax seed holder (13). The end having the cold wax seed (14) is lowered into the molten wax (12) and is slowly pulled out from molten wax (12) by means of the wax seed holder (13). When the wax seed (14) is pulled out from the molten wax (12), it pulls a wax thread (15) out from the melt (12).

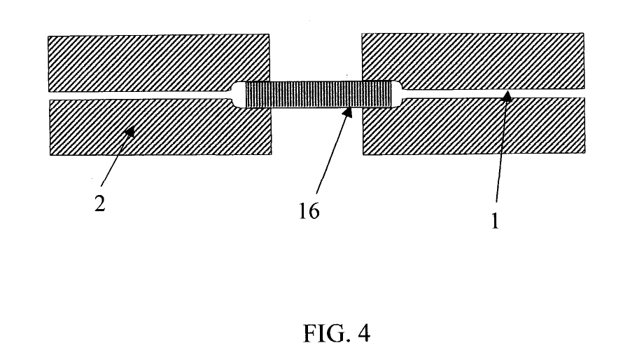

FIG. 4 shows the scheme for a stand-off interconnection. Two silicone elastomer substrates (2) have molded microchannels (1) embedded in them. A fused silica capillary tube (16) having an outer diameter greater than the inner diameter of molded microchannel (1) is force-fitted into molded microchannel. The fused silica capillary tube (16) is long enough so that the two silicone elastomer substrates (2) are far apart from each other.

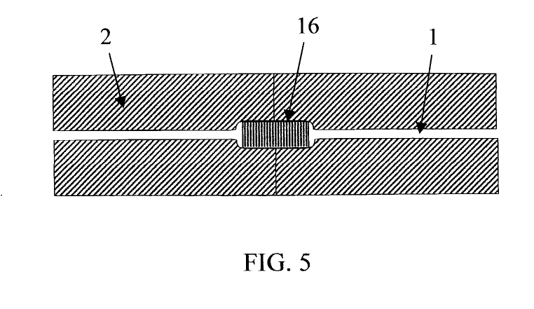

FIG. 5 shows the schematic for a closed-scheme interconnection. Two silicone elastomer substrates (2) have molded microchannels (1) embedded in them. A fused silica capillary tube (16) having an outer diameter greater than the inner diameter of molded microchannel (1) is force-fitted into molded microchannel. The fused silica capillary tube (16) is short enough so that the two silicone elastomer substrates (2) are in contact.

### DETAILED DESCRIPTION OF THE PREFERRED EMBODIMENTS

One embodiment of the present invention is a sacrificial flexible molding method which may be used to form channels, capillaries, reservoirs or other cavities in nanofluidic or microfluidic systems or devices, such as those employed in NEMS (nano electro mechanical systems) and MEMS (micro electro mechanical systems) devices. Nanofluidic and microfluidic systems and devices are those which have one or more extremely small fluid channels, reservoirs and/or cavities (typically having at least one dimension which is less than a millimeter, or a few micrometers, or a few nanometers). For example, a microchannel is a fluid channel having a very small diameter, particularly a diameter less than one millimeter, or even less than 500 micrometer. For example, a nanochannel is a fluid channel having a very small diameter, particularly a diameter of a few nanometers or less. One or more sacrificial layer/structure components (typically made of wax or other sacrificial material) in the shape of the desired channel(s), reservoir(s) and/or cavity(ies) are encapsulated in a polymeric material (such as silicone elastomer). The resulting structure is then placed into an appropriate solvent (such as acetone in the case of wax). The solvent will dissolve away the wax components, leaving behind the channel(s), reservoir(s) and/or cavity(ies) within the polymeric material. It will be understood that other dissolvable or developable or etchable material may be used in place of wax, and acetone is merely one suitable solvent for dissolving away the wax (or other dissolvable material). It will also be understood that for optically or lithographically developable material, a suitable chemical process will be used for developing the developable material (such as photo resist) and for etchable material, a suitable etchant may be used to etch away the etchable material. It will also be understood that heat may be used in conjunction with (or even in place of) the solvent in order to dissolve (or melt) the wax.

In one particular embodiment, a three dimensional nano/micro thread or nano/micro structures of sacrificial wax or other dissolvable sacrificial material (or other developable material such as photo resist or other etchable material such as metal or injection molded plastic or other polymer or epoxy or suitable sacrificial material), is first formed and suspended, around which is pored the polymer (typically silicone elastomer) or epoxy in liquid form or any other suitable substrate material, until the sacrificial wax or sacrificial material is totally and/or partially submerged. When the polymer or the epoxy or suitable substrate material hardens, the complete system is placed in an appropriate solvent (typically acetone) or developer or etchant which removes the sacrificial layer/structure (such as wax) starting from an area exposed (exposed out from the substrate encapsulation) to the solvent or developer or etchant or suitable chemical, leaving the three-dimensional channel matrix originally formed by the sacrificial layer/structure. Multiple sacrificial threads (such as wax threads) can be used, and may be interconnected in any desired configuration to form multiple interconnected channels. In addition, the wax threads (or other sacrificial threads) may similarly be connected to other three-dimensional wax structures (or other sacrificial structures) in order to form interconnected reservoirs and/or cavities. In other words, the polymer will encapsulate a pre-formed network of sacrificial wax threads (or otherwise configured sacrificial threads) or other connected wax (or other sacrificial material) configurations which will ultimately become nano and/or micro channels, reservoirs and cavities in the polymeric substrate (or motherboard). This constitutes a new method of forming nano/microchannels and cavities in plastic substrates, by batch processing, for nano/microfluidic applications.

Wax thread, useful in the methods of the present invention, may be prepared by any of a variety of techniques. One particular method of the present invention comprises pulling wax filaments from molten wax using a cold wax seed (which is in solid phase) attached to a rod, wire or string, or the use of any other cold surface on which the molten wax thread can solidify. A volume of wax is heated until melted, and the rod containing the wax seed (or the cold surface) is dipped into the molten wax and pulled out. As the rod containing the wax seed (or the cold surface) is pulled away from the volume of molten wax, a thread of wax is formed. The cross-sectional diameter of the thread can be altered by adjusting, among other things, the temperature of the melt, viscosity of the melt, the diameter of the wax seed or cold surface, the rate at which the wax thread is pulled out from the melt, and the ambient temperature. Of course wax thread may be produced by a variety of other methods, such as extrusion. Moreover, the cross-sectional profile of the wax thread is controlled by the seed or extrusion aperture.

Instead of using wax thread, it is also contemplated that various other wax (or other sacrificial material such as photoresist, metal, ceramic, polymer or silicon) form may be used. For example, a “silk screening” type process may be used (e.g., using a stainless steel mesh), particularly for planar configurations. In addition, sacrificial wax (or other sacrificial material) layers may be cut from a thin wax film (e.g., using a sharp heated tool), particularly when forming reservoirs or other cavities. A wax film may be produced, for example, by depositing the wax onto a metal foil and thereafter detaching the foil by heating. It is also contemplated that the sacrificial wax structure(s) may be fabricated using a heated stamp comprising a micromachined negative formed, for example, in silicon or glass.

In order to form interconnected structures (such as a series of interconnected microchannels), the wax (or other sacrificial material) structures (such as wax threads) may be joined together. In one embodiment, the joining surfaces of the wax structures may simply be locally heated in order to fuse the structures to one another (e.g., using a soldering tip held adjacent to the ends of the wax threads to be joined when doing by hand). In this manner, it is even possible to produce microfluidic junctions which connect any number of microfluidic channels.

One particular technique for fabricating microchannels (or cavities or reservoirs or structures) in a structure (or substrate) comprises first providing a base, such as by pouring a silicone elastomer into a simple mold. Thereafter, the wax (or other sacrificial material) threads or filaments are positioned on this base in the desired microchannel (or other structural) arrangement. Silicone elastomer (or other substrate material) is then poured over top of the wax (or other sacrificial material) threads or filaments into the mold, thereby encapsulating the wax. After the silicone elastomer has hardened, the cast is removed from the mold and immersed in acetone (or developer or etchant or suitable chemical) in order to dissolve away the wax (or other sacrificial material) and form the microchannels and related configurations.

One particular advantage of the fabrication methods of the present invention is that nanofluidic or microfluidic channels (or structures or cavities) of any possible shape and configuration can be fabricated. For example, spiral microchannels may easily be formed in a substrate using the methods of the present invention. This is the only method known to the inventors which will allow formation of a continuous three-dimensional channel (non-discrete) such as the latter spiral configuration. Such three-dimensionality becomes very important, for example, in the achievement of mixing in nano/microfluidics, where the typically ultra small Reynolds numbers lead to sustained separation of combined fluids. The present technique trivially allows the formation of necessary configurations to achieve effective non-diffusive mixing.

In addition, the nanofluidic or microfluidic channels (or structures or cavities) in one substrate (or “motherboard”) may be interconnected with those provided in another substrate. Interconnection for example may be achieved using, a fused silica capillary tube which may be force-fitted into microchannels in adjacent substrates such that the capillary tube acts as a convenient interconnect, which not only connects the two substrates to one another, but also provides fluid communication between the microchannels in separate substrates. External nanofluidic or microfluidic components (such as replaceable reservoirs) may even be connected to a microchannel in a substrate using this convenient “plug-in” method. Moreover, this interconnection scheme may be extended for connection of multiple layerized levels of complex polymeric nano/microfluidic substrate motherboards, using small sections of fused silica or other appropriate tubing or capillaries. This method has considerable advantages over many other possible schemes, because the present scheme requires no lips or bosses which eliminates the loss of stacking volume.

In one particular embodiment, the process of fabrication of the sacrificial layers and encapsulation of the sacrificial layers are automated by having a machine which builds up the sacrificial layer structure while filling the area around the structure with the substrate. The machine has multiple nozzles for injecting the sacrificial layer material. The machine also has multiple nozzles for injecting the substrate material.

In one particular embodiment, the methods of the present invention are also useful in producing or incorporating various other nanofluidic or microfluidic components such as valves (e.g., membrane valves, pinch valves, etc.), mixing chambers, pumps and the like. In fact, when the substrate (or “motherboard”) comprises a silicone elastomer (or latex or similar material), the inherent flexibility of the silicone elastomer will facilitate formation of these structures. Many silicone elastomers are also bio-compatible. In addition, multiple layers of polymer (which may be interspersed with layers of other materials) can even be bonded together to form various three-dimensional configurations.

In one particular embodiment, small pinch valves are fabricated on the silicone elastomer (or similar material) substrate which operate by pinching off the substrate itself. The micro channels are formed using the above sacrificial wax technique, and these channels are merely pinched to stop the flow of fluids to realize the valving action. A wound or micromachined solenoid is used as the magnetic actuator. A schematic diagram of the three-dimensional polymeric microfluidic pinch valve is shown in FIG. 1. The silicone elastomer (2) has a microchannel (1) (which has been formed by etch-away of a sacrificial wax thread) which may be closed by pinching shaft (6). In FIG. 1 the normally closed valve is shown in an activated “open” position. Shaft (6) is spring-loaded with an adjustable magnetic spring (7), consisting of miniature planar or disk permanent magnets (7), having an adjustable infinite number of spring constants. The magnetic spring (7) is realized by placing like poles of two permanent magnets (7), facing each other. Here the valve is normally closed, since the force exerted by the repulsion of the magnets (7) pinch off the microchannel (1). When the solenoid (3), consisting of an electrical winding, is activated, the shaft (6) pinching the micro channel (1) is movedupwards due to the magnetic attraction of the ferromagnetic disk (4) towards the solenoid (3), removing the constriction in the microchannel (1), thereby allowing the fluids through the microchannel (1). Normally-open valves are also fabricated using the same principle, with attracting magnetic pole faces in the magnetic spring (7), but with the ferromagnetic disk (4) placed above the solenoid (3). Also, the actuator shown in FIG. 1 can be replaced by a magnetostrictive actuator as shown in FIG. 2. In FIG. 2 all numbers correspond to those shown in FIG. 1 except that a magnetostrictive material (9) is added for actuation, replacing the magnetic spring (7) and the ferromagnetic disk (4) in FIG. 1

Fabrication Processes

Making Wax Thread or Filaments

A novel method is utilized to make the wax thread, which may be used as a sacrificial layer during the processing. The sacrificial wax threads (15) may be easily formed using a Czchrolsky-like pulling approach with a wax seed (14) attached to a capillary fused silica tube 13) (or similar variation noted earlier). In this method, the wax is heated up on a hot plate or other vessel until the wax is molten (12). Wax wicks up into the capillary tube (13) (which serves as a handle and thus also contains the wax seed (14)) and is pulled as a thread from the melt (12). The cross-sectional diameter of the wax thread depends mainly on the following four parameters: (i) the temperature of the melt (12), (ii) diameter of the fused silica tube (13), (iii) the rate at which the wax thread (15) is pulled from the melt (12) and (iv) the temperature of the surrounding area (rate of heat dissipation from the wax thread (15) to the atmosphere). This sequence has been confirmed by hand but could be easily automated in production.

Interconnection Scheme for Polymeric Motherboards

The inter-connection scheme was developed in order to integrate microfluidic components onto the polymeric substrates and also, to make inter-connections between polymeric motherboards. As schematically shown in FIG. 4 and FIG. 5, an interconnect (16) may be done by simply force fitting commercially available fused silica capillary tubes (16) directly into the somewhat smaller molded micro channels (1) (having circular cross section in this case) on the silicone elastomer substrate (2). The outside of the fused silica capillary (16) was coated with polyamide which minimizes the inclination for breakage and provides a better seal between fused silica (16) and silicone elastomer substrate (2). The friction between the capillary (16) and elastomer (2) is a major factor when considering how much pressure can be applied in the channels (1). Of course, tighter the seal and higher the friction between the capillary (16), and the elastomer (2), the higher is the pressure that can be applied within the channels (1) without leakage or disconnection of the interconnects (16). These interconnects (16) were successfully tested to withstand a pressure of more than 60 psi. Also, the maximum pressure that an interconnect (16) withstands depends on the ratio between the diameter of the channel (1) formed in the elastomer (2) and the outer diameter of the fused silica capillary (16).

[image]

[image]

[image]

[image]

[image]

[image]

[image]

[image]

[image]

[image]

[image]

[image]

[image]

[image]

What we claim is:

1. A method of fabricating a substrate having at least one 3-dimensional nanofluidic and/or 3-dimensional microfluidic component and/or system, comprising:
(a) providing a substrate having at least one dissolvable developable or etchable component arranged in the shape of the desired 3-dimensional nanofluidic and/or microfluidic component; and
(b) dissolvable or developable or etchable component embedded in the substrate; and
(c) dissolving or developing or etching said dissolvable or developable or etchable component.

2. The method of claim 1, wherein said dissolvable or developable or etchable component comprises a sacrificial material such as wax or photoresist or polymer or monomer or metal or any sacrificial material.

3. The method of claim 1, wherein said substrate comprises polymers such as silicone elastomer (poly di methoxy siloxene or PDMS) or poly amide or PMMA or plastic or latex or epoxies such as epoxy photoresist or ultra violet cured epoxy or heat cured epoxy or room temperature cured epoxy.

4. The method of claim 2, wherein said dissolving or developing or etching step comprises placing said substrate into a solvent or developer solution or etching solution which is capable of dissolving or developing or etching the said sacrificial layer.

5. The method of claim 2, wherein said nanofluidic or microfluidic component comprises a nanochannel or microchannel, and said component comprises of a wax thread.

6. The nanofluidic and/or microfluidic component of claim 1, further comprises of nano/micro cavities and nano/micro channels and nano/micro mixing chambers and micro pinch valves and nano/micro reservoirs and nano/micro constant pressure reservoirs.

7. The fabrication method of claim 1, further comprises, a method to automate the fabrication of nanofluidic and/or microfluidic components and/or systems comprising the method of claim 1.

8. Claim 1 further comprises, a method of fabricating 3-dimensional nano and/or micro structures on the surface of a substrate by partially embedding the sacrificial layer in/on the substrate.

9. A method of fabricating 3-dimensional wax thread or filaments or strings or strands, by pulling it from melt or by extrusion.

10. The method of claim 9, wherein said wax thread is pulled from hot liquefied wax by using a solid seed such as a piece of cold wax attached to a rod.

11. The method of claim 9, wherein said wax is extruded by slightly increasing the temperature of solid wax such that the wax becomes soft and then extruding the wax which has become soft.

12. The method of claim 9, wherein said wax is extruded by pouring hot liquefied wax into molds.

13. A method to pattern wax using a silk screen with wax being totally dissolved by a solvent.

14. A method to pattern heated wax using a stainless steel screen.

15. A method to interconnect polymer fluidic channels.

16. A method to fabricate pinch valve in or on the molded polymer breadboard to open or close the formed microchannels using a magnetic spring.

17. A method to fabricate pinch valve in or on the molded polymer breadboard to open or close the formed microchannels using a magnetostrictive actuator.

18. A microfluidic device produced by the method of claim 1.
